(19) United States
(12) Patent Application Publication
(10) Pub. No.: US 2018/0141130 A1
(43) Pub. Date: May 24, 2018

(54) MACHINING TOOL

(71) Applicant: GUEHRING KG, Albstadt (DE)

(72) Inventors: Stefan SATTEL, Strassberg (DE); Immo Garrn, Ertingen (DE); Manfred Schwenck, Albstadt (DE)

(73) Assignee: GUEHRING KG, Albstadt (DE)

(21) Appl. No.: 15/807,770

(22) Filed: Nov. 9, 2017

Related U.S. Application Data
(63) Continuation of application No. PCT/DE2016/000197, filed on May 10, 2016.

(30) Foreign Application Priority Data
May 12, 2015 (DE) 10 2015 208 743.3

(51) Int. Cl. B23B 27/14; C23C 14/48; C23C 14/06

(52) U.S. Cl. CPC B23B 27/148; C23C 14/48; C23C 16/27; B23B 2200/3627; C23C 14/0641

(57) ABSTRACT

The invention relates to a machining tool comprising a substrate surface made of a hard metal or a ceramic material; the substrate surface contains carbide-based and/or nitride-based and/or oxide-based hard particles embedded in a cobalt-containing binder matrix, and the substrate surface contains additional atoms implanted using ion beams of at least one species of cations.

The present invention pertains to a machining tool according to the preambles of claims 1 and 2.

Various types of machining tools with a tool head, a tool shaft and a clamping section for being accommodated in a tool receptacle are known from the prior art.

In the region of their cutting edge, such tools feature functional areas that are adapted to the specific requirements of the materials to be machined.

The aforementioned tools are particularly realized in the form of drilling, milling, counterboring, turning, threading, contouring or reaming tools and may feature cutting bodies or guide rails as functional areas, wherein the cutting bodies may be realized, for example, in the form of indexable inserts and the guide rails may be realized, for example, in the form of support rails.

Tools of this type usually feature functional areas that provide the tool with a high wear resistance for machining highly abrasive materials.

The assortment of products offered by the applicant has provided users with a broad variety of tools made of hard metal and/or cermet for quite some time. A hard metal typically contains sintered materials of hard particles and a binder material, for example tungsten carbide grains, wherein these tungsten carbide grains form the hard materials and the cobalt-containing binder matrix serves as binder for the tungsten carbide grains and provides the layer with the required toughness for the tool.

Furthermore, DE 20 2005 021 817 U1 of the applicant of the present patent application describes tool heads for more demanding applications, which consist of a hard material with at least one functional layer that features a superhard material such as cubic boron nitride (CBN) or polycrystalline diamond (PCD).

A thusly coated tool makes it possible to achieve long service lives with respect to the mechanical and thermal requirements of drilling, milling or reaming processes.

Methods for applying polycrystalline diamond films onto non-diamond substrates have also been known for quite some time. For example, U.S. Pat. No. 5,082,359 describes the application of a polycrystalline diamond film by means of chemical vapor deposition (CVD).

In the method described in this prior art document, a series of discrete nucleation points, which typically have the shape of craters, is produced on the surface of the functional area of a tool to be coated.

According to U.S. Pat. No. 5,082,359, these craters, which serve as nucleation sites for the subsequent diamond deposition, can be produced with a number of methods, for example by means of laser evaporation and chemical etching or plasma etching processes, in which a correspondingly patterned photoresist is used, or also by means of a focused ion beam (focused ion beam milling).

In U.S. Pat. No. 5,082,359, it is disclosed that craters with a spacing of less than 1 μm can be produced in the substrates with a focused ion beam of Ga+ with a kinetic energy of 25 KeV by focusing the Ga+ ion beam on a diameter of less than 0.1 μm.

Typical materials used in the semiconductor industry such as germanium, silicon, gallium arsenide and polished wafers of monocrystalline silicon are cited as substrates in U.S. Pat. No. 5,082,359, wherein titanium, molybdenum, nickel, copper, tungsten, tantalum, steel, ceramic, silicon carbide, silicon nitride, silicon aluminum oxynitride, boron nitride, aluminum oxide, zinc sulfide, zinc selenide, tungsten carbide, graphite, silica glass, glass and sapphire are cited as other useful substrates.

Although ion beams in the form of a focused ion beam of Ga+ were therefore already used for substrate pretreatments prior to a CVD diamond deposition in the prior art according to U.S. Pat. No. 5,082,359, only heavy Ga+ cations were used in this case, wherein these heavy Ga+ cations knock the Co atoms out of the metal lattice of the binder matrix—after collision with the Co atoms of the binder matrix—such that the binder matrix is significantly depleted of cobalt. Consequently, the use of ion beams of heavy Ga+ seamlessly fits into the “cobalt depletion” model and merely represents an alternative to the chemical etching methods known from the prior art and therefore a massive removal of Co atoms from the binder matrix.

Furthermore, a method for producing a diamond coating on a functional area of a machining tool is known from non-prepublished German patent application 10 2014 210 371.1 of the applicant of the present application of Jul. 2, 2014 with the title “Diamond-coated machining tool and method for its manufacture,” wherein an ion beam of positively charged ions is used for pretreating the substrate surface prior to a CVD coating process in this method. In contrast to the use of ion beams with heavy ion species in the prior art according to U.S. Pat. No. 5,082,359, the cobalt essentially remains in the binder matrix during the irradiation of the substrate surface with the significantly lighter ion species N+, N++ and/or C+ in accordance with DE 10 2014 210 371.1 and therefore leads to a diamond coating that adheres much better than in the prior art.

As mechanism for the Co inactivation for the CVD diamond coating, DE 10 2014 210 371.1 proposes that cobalt can due to the irradiated light ions transform into cobalt nitrites or cobalt carbonitrides or even cobalt carbides, which do not have the catalytic effect for the conversion of the cubic diamond phase into the hexagonal graphitic phase, such that the cubic diamond crystals have sufficient time to grow on the substrate surface without an in situ reconversion into graphite taking place.

It should therefore be noted that the irradiation of a hard metal substrate with an ion beam according to DE 10 2014 210 371.1 merely serves for preparing the substrate for the immediately following diamond coating. Due to the inactivation of the catalytically active cobalt matrix, the irradiation with cations favorably affects the shift of the graphite-diamond equilibrium toward diamond. In this way, the adhesion of the diamond layer on the substrate surface pretreated with the ion beam is drastically improved.

Diamond-coated hard metal tools or cermet tools naturally have positive effects on the wearing protection of the tool, as well as its service life during continuous use.

However, one common aspect of all diamond coating methods is the significantly higher process effort for the growth of the cubic diamond crystals on the hard metal substrates, which can amount to several days and therefore results in a significantly higher price of the obtained tool products in comparison with tools of hard metal or cermet materials, which are not diamond-coated.

Based on known hard metal tools, in which a cobalt-containing binder matrix for embedding hard particles proved to be effective for quite some time in the prior art, the present invention therefore aims to make available machining tools, which already have a significantly greater hardness than that achieved so far in the prior art with pure hard metal substrates without a diamond coating.

This objective is attained with the characteristics of claims 1 and 2.

The present invention particularly pertains to a machining tool with a substrate surface made of a hard metal or a ceramic material, wherein the substrate surface contains carbide-based and/or nitride-based and/or oxide-based hard particles, which are embedded in a cobalt-containing binder matrix, and wherein the substrate surface contains additional atoms implanted by means of ion beams of at least one cation species.

An alternative embodiment of the present invention pertains to a machining tool with at least one structural modification on a substrate surface, wherein the tool has a substrate surface made of a hard metal or a ceramic material and the substrate surface contains carbide-based and/or nitride-based and/or oxide-based hard particles, which are embedded in a cobalt-containing binder matrix, wherein the structural modification can be achieved by treating the substrate surface with a positively charged ion beam of at least one species of ionized atoms, and wherein at least part of the atoms underlying the ion species remains in the substrate structure as additional atoms.

In this context, it was very surprisingly determined that the treatment of a hard metal surface with an ion beam of positively charged ions not only leads to the incorporation of these ions into the crystal lattice of the hard metal substrate, but also to a structural modification that improves properties such as rigidity, edge stability, welding-up tendency and reactivity and particularly increases the hardness of the substrate surface. In contrast to the assumption in non-prepublished DE 10 2014 210 371.1, it appears that not only cobalt nitrites and cobalt carbides can form, but lattice positions and/or interstitial positions in the hard metal structure are additionally occupied by foreign atoms. In this way, mechanical properties such as, for example, the hardness of the hard metal or cermet substrate irradiated with ions can be adjusted and improved as needed. Consequently, a substantial hardness and a long service life of the irradiated tools can also be achieved without a subsequent diamond coating.

In contrast to the non-prepublished prior art according to DE 10 2014 210 371.1, in which the ion beam treatment merely serves as a layer pretreatment for the subsequent diamond coating, the irradiation of hard metal or cermet substrates by means of cations therefore takes on a significance of its own.

The dependent claims define preferred embodiments of the present invention:

A preferred tool is particularly characterized in that the hard particles are selected from the group consisting of: the carbides, carbonitrides and nitrides of the non-radioactive metals of the IV., V., VI. and VII. subgroups of the periodic table of the elements and boron nitride, particularly cubic boron nitride; as well as oxidic hard materials, particularly aluminum oxide and chromium oxide; as well as, in particular, titanium carbide, titanium nitride, titanium carbonitride; vanadium carbide, niobium carbide, tantalum carbide; chromium carbide, molybdenum carbide, tungsten carbide; manganese carbide, rhenium carbide, as well as mixtures and mixed phases thereof. This assortment of hard particles makes it possible to flexibly adapt the intended use of the tool to the respective requirements.

A preferred tool is a tool, in which the binder matrix for binding the aforementioned hard particles also contains—in addition to cobalt—aluminum, chromium, molybdenum and/or nickel. In this way, the toughness of the substrate can be adjusted as required without lowering the binding capacity for the hard particles.

In another preferred embodiment of the present invention, a tool comprises a ceramic material that is formed of a sintered material of the above-described hard particles and bound in a binder matrix that—in addition to cobalt—may also contain aluminum, chromium, molybdenum and/or nickel.

For example, a sintered hard metal of carbide or carbonitride may serve as ceramic material. Such materials make it possible to achieve an enormous hardness, as well as a high heat and wear resistance and a low reactivity.

The following atoms proved to be particularly suitable for use as additional atoms, which according to the invention can be introduced into the substrate layer by means of ion irradiation: lithium, boron, carbon, silicon, nitrogen, phosphorus and/or oxygen, wherein nitrogen and/or carbon is preferred.

Cations of the aforementioned atoms particularly make it possible to achieve structural modifications that altogether improve the layer properties in every respect. In this case, the cations, which are introduced into the metal lattice structure with high energy, presumably occupy additional lattice positions without knocking a significant quantity of atoms out of the lattice structure. A considerably increased hardness can be achieved, in particular, due to the additional lattice positions and the introduced mass of additional atoms. In this case, poly-charged cations such as B+++, C+++ and N++, but also positively mono-charged and double-charged particles, the majority of which are incorporated into the substrate layer, particularly also occur—depending on the energy.

The penetration depth of the additional atoms incorporated by means of the ion beam measured from the outer surface of the tool may be as high as approximately 10 μm. In this way, exceptionally stable and wear-resistant layers are obtained.

The ion beam used for the present invention is generated by means of a commercially available ion beam generator.

Experiments have shown that an ion beam with a kinetic energy of 3.2×10⁻¹⁵ J to 3.2×10⁻¹⁴ J [20 KeV to 200 KeV] is optimally suited for incorporating additional atoms into the substrate layer.

The treatment of the substrate surface by means of ion beams is typically carried out in a vacuum at 20° C. to 450° C., particularly 300° C. to 450° C.

The tools according to the present invention are preferably realized in the form of rotating or stationary tools, particularly drilling, milling, counterboring, turning, threading, contouring or reaming tools. The complete assortment of products with improved functional areas is thereby made available to users.

For example, the tool may conventionally have a monolithic or modular design.

The tools according to the present invention may naturally also be realized in such a way that a cutting body, particularly an insert, preferably in indexable insert, is provided on a support body and/or at least one guide rail, particularly a support rail, is provided.

A high-speed tool steel, particularly a steel with the DIN key to steel 1.3343, 1.3243, 1.3344 or 1.3247, can preferably used as material for the substrate.

However, the tools naturally may, if so required, also be diamond-coated although this is not the primary objective of the present invention and unnecessary for most applications. This would be carried out subsequent to the treatment with the ion beam, for example, as described in non-prepublished DE 10 2014 210 371.1, wherein the tool would then feature at least one functional area that is diamond-coated, e.g. by means of CVD.

A person skilled in the art is quite familiar with such CVD diamond deposition methods since 1982 (see MATSUMOTO, S., SATO, Y., KAMO, M. & SETAKA, N. (1982): Japan J Appl Phys; 21(4), pp 183-185: Vapor deposition of diamond particles from methane). With respect to the diamond coating of hard metal substrates by means of CVD methods, we also refer, for example, to the review article by HAUBNER et al. [HAUBNER, R. and KALSS, W. (2010): Int. Journal of Refractory Metals and Hard Materials 28, pp. 475-483: “Diamond deposition on hard metal substrates—Comparison of substrate pretreatments and industrial applications”].

Typical layer thicknesses for the diamond coating on the tool surfaces may lie in the range between 3 and 15 μm, particularly between 6 and 12 μm.

Other advantages and characteristics can be gathered from the description of concrete exemplary embodiments.

### EXAMPLE 1

Hard metal tools made of a hard metal with 10% Co by mass and an average WC grain size of 0.6 μm (Gühring brand name DK460UF) were in accordance with the invention irradiated with an ion stream of nitrogen ions for 3.5 h, wherein the ion stream was generated with a voltage of 30 kV at a plasma current of 3 mA and a nitrogen pressure of 1×10⁻⁵. In this case, a temperature of approximately 400° C. was adjusted on the tool.

A commercially available ion generator was used for generating the ion beam. The ion generator “Hardion” of the firm Quertech, Caen, particularly was used in this case.

In this example, N++ ions are generated during the irradiation, wherein said ions essentially occupy lattice positions and/or interstitial positions in the structure of the metal lattice and potentially can also partially react with the existing transition metals in order to form corresponding metal nitrides.

In measurements of the Vickers hardness according to DIN EN ISO 6507-1, it was determined that the tools acted upon with the nitrogen ion beam had a Vickers hardness, which was approximately 10 to 15% higher than that of a non-irradiated tool.

### EXAMPLE 2

Tools made of a high-speed steel with the key to steel 1.3343 (Gühring brand name HSS) were in accordance with the invention irradiated with an ion stream of nitrogen ions for 3 h, wherein the ion stream was generated with a voltage of 30 kV at a plasma current of 3 mA and a nitrogen pressure of 1×10⁻⁵. In this case, a temperature of approximately 350° C. was adjusted on the tool.

A commercially available ion generator according to Example 1 was likewise used for generating the ion beam in this case.

In measurements of the Vickers hardness according to DIN EN ISO 6507-1, it was determined that the HSS tools acted upon with the nitrogen ion beam had a Vickers hardness, which was approximately 20 to 25% higher than that of a non-irradiated tool.

### EXAMPLE 3

Tools made of a high-speed steel with the key to steel 1.3247 (Gühring brand name HSS-E or M42) were in accordance with the invention irradiated with an ion stream of nitrogen and boron ions (proportion approximately 5% by atom) for 3 h, wherein the ion stream was generated with a voltage of 40 kV at a plasma current of 4 mA and a pressure of 1×10⁻⁵. In this case, a temperature of approximately 370° C. was adjusted on the tool.

A commercially available ion generator according to Example 1 was likewise used for generating the ion beam in this case.

In measurements of the Vickers hardness according to DIN EN ISO 6507-1, it was determined that the HSS-E tools acted upon with the nitrogen/boron ion beam had a Vickers hardness, which was approximately 20 to 25% higher than that of a non-irradiated tool.

### EXAMPLE 4

Tools made of a high-speed steel with the key to steel 1.3343 (Gühring brand name HSS) were in accordance with the invention irradiated with an ion stream of nitrogen and carbon ions (proportion approximately 50% by atom) for 3 h, wherein the ion stream was generated with a voltage of 40 kV at a plasma current of 4 mA and a pressure of 1×10⁻⁵. In this case, a temperature of approximately 360° C. was adjusted on the tool.

A commercially available ion generator according to Example 1 was likewise used for generating the ion beam in this case.

In measurements of the Vickers hardness according to DIN EN ISO 6507-1, it was determined that the HSS tools acted upon with the nitrogen/carbon ion beam had a Vickers hardness, which was approximately 25 to 35% higher than that of a non-irradiated tool.

1. A machining tool, comprising:
a substrate surface made of a hard metal or a ceramic material, wherein the substrate surface contains carbide-based and/or nitride-based and/or oxide-based hard particles, which are embedded in a cobalt-containing binder matrix,
the substrate surface containing additional atoms implanted by means of ion beams of at least one cation species.

2. A machining tool, comprising:
a substrate surface, wherein at least one structural modification is on the substrate surface, the substrate surface made of a hard metal or a ceramic material and the substrate surface contains carbide-based and/or nitride-based and/or oxide-based hard particles, which are embedded in a cobalt-containing binder matrix,
wherein the structural modification can be achieved by treating the substrate surface with a positively charged ion beam of at least one species of ionized atoms, wherein at least part of the atoms underlying the ion species remains in the substrate structure as additional atoms.

3. The tool according to claim 1, wherein the hard particles are selected from the group consisting of: the carbides, carbonitrides and nitrides of the non-radioactive metals of the IV., V., VI. and VII. subgroups of the periodic table of the elements, boron nitride, oxidic hard materials, titanium carbide, titanium nitride, titanium carbonitride, vanadium carbide, niobium carbide, tantalum carbide, chromium carbide, molybdenum carbide, tungsten carbide, manganese carbide, and rhenium carbide, as well as mixtures and mixed phases thereof.

4. The tool according to claim 1, wherein the binder matrix also contains aluminum, chromium, molybdenum and/or nickel.

5. The tool according to claim 3, wherein the binder matrix also contains aluminum, chromium, molybdenum and/or nickel.

6. The tool according to claim 5, wherein the ceramic material is a sintered hard metal of carbide or carbonitride.

7. The tool according to claim 1, wherein the additional atoms are selected from the group consisting of: lithium, boron, carbon, silicon, nitrogen, phosphorus and oxygen.

8. The tool according to claim 1, wherein the additional atoms are arranged within the substrate structure at a depth of up to approximately 10 μm measured from the outer surface of the tool.

9. The tool according to claim 1, wherein the tool is a rotating or stationary tool.

10. The tool according to claim 1, wherein the tool has a monolithic or modular design.

11. The tool according to claim 1, wherein at least one cutting body is provided on a support body and/or at least one guide rail is provided.

12. The tool according to claim 1, wherein the substrate is made of a high-speed tool steel.

13. The tool according to claim 1 wherein the tool comprises at least one functional area that is diamond-coated by means of CVD.

14. The tool according to claim 1, wherein the hard particles are selected from the group consisting of cubic boron nitride, aluminum oxide and chromium oxide.

15. The tool according to claim 1, wherein the additional atoms are selected from the group consisting of nitrogen and carbon.

16. The tool according to claim 1, wherein the tool is a drilling, milling, counterboring, turning, threading, contouring or reaming tool.

17. The tool according to claim 11, wherein the cutting body is an insert.

18. The tool according to claim 11, wherein the cutting body is an indexable insert.

19. The tool according to claim 11, wherein the guide rail is a support rail.

20. The tool according to claim 1, wherein the substrate is made of a steel with the DIN key to steel 1.3343, 1.3243, 1.3344 or 1.3247.
